(19) United States
(12) Patent Application Publication
(10) Pub. No.: US 2026/0173410 A1
(43) Pub. Date: Jun. 18, 2026

(54) CAPACITOR STRUCTURE AND MANUFACTURING METHOD THEREOF

(71) Applicant: Taiwan Semiconductor Manufacturing Co., Ltd., Hsinchu (TW)

(72) Inventors: Hsiang-Ku Shen, Hsinchu (TW); Shih-Cheng Chou, Hsinchu (TW)

(21) Appl. No.: 19/189,655

(22) Filed: Apr. 25, 2025

Related U.S. Application Data
(60) Provisional application No. 63/734,962, filed on Dec. 17, 2024.

(51) Int. Cl. H10D 1/00; H01L 23/48; H10D 1/68

(52) U.S. Cl. CPC H10D 1/042; H10D 1/68; H10W 20/20

(57) ABSTRACT

A method includes forming a first electrode, including depositing a first layer of a conductive material and depositing a second layer of the conductive material on the first layer of the conductive material, forming a first insulator layer on the second layer of the conductive material; and forming a second electrode, including depositing a third layer of the conductive material over the first insulator layer and depositing a fourth layer of the conductive material over the third layer of the conductive material.

### PRIORITY CLAIM AND CROSS-REFERENCE

This application claims the benefit of U.S. Provisional Application No. 63/734,962, filed on Dec. 17, 2024, which application is hereby incorporated herein by reference.

### BACKGROUND

Metal-Insulator-Metal (MIM) capacitors have been widely used in functional circuits such as mixed signal circuits, analog circuits, Radio Frequency (RF) circuits, Dynamic Random-Access Memories (DRAMs), embedded DRAMs, and logic operation circuits. In system-on-chip applications, different capacitors for different functional circuits have to be integrated on a same chip to serve different purposes. For example, in mixed-signal circuits, capacitors are used as decoupling capacitors and high frequency noise filters. For DRAM and embedded DRAM circuits, capacitors are used for memory storage, while for RF circuits, capacitors are used in oscillators and phase-shift networks for coupling and/or bypassing purposes. For microprocessors, capacitors are used for decoupling.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a package component including one or more Metal-Insulator-Metal (MIM) capacitors, in accordance with some embodiments.

FIGS. 2, 3, 4, 5, 6, 7, 8, 9, 10, 11, 12, 13, 14, 15, and 16 illustrate cross-sectional views of intermediate stages in the formation of a capacitor, in accordance with some embodiments.

FIG. 17 illustrates a cross-sectional view of an intermediate stage in the formation of a capacitor, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A capacitor and the method of forming the same are provided. In accordance with some embodiments, the formation of a Metal-Insulator-Metal (MIM) capacitor includes forming the electrodes as a bi-layer structure including an upper layer over a lower layer. The upper layer and the lower layer may be formed of the same material, but deposited using two different deposition techniques. The material of the upper layer may be deposited using a deposition technique that forms the material of the upper layer such that the interface between the upper layer and an overlying insulator layer is improved. In this manner, the capacitor may be less sensitive to subsequent processing, such as hydrogen annealing or the like, and thus the reliability of the capacitor may be improved.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

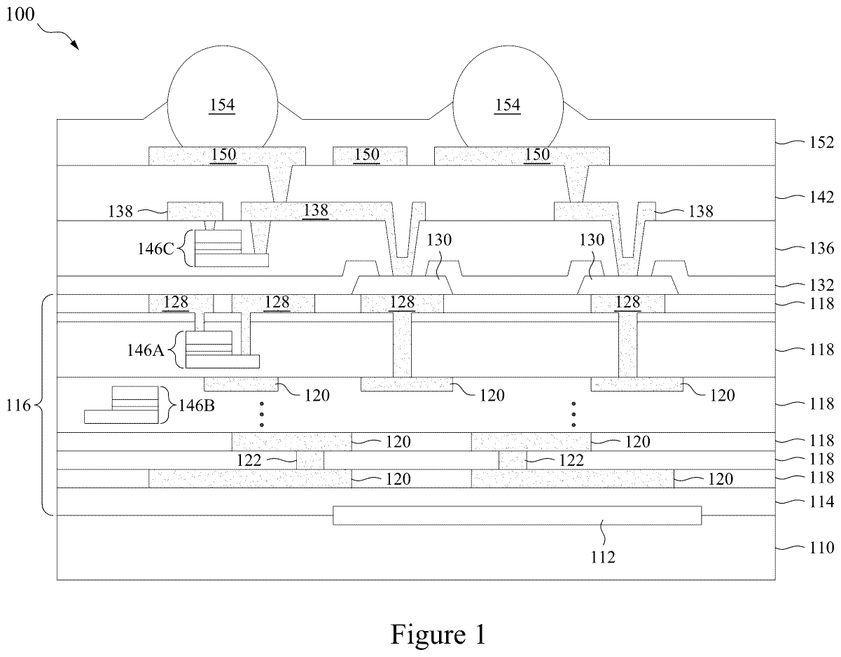

FIG. 1 illustrates a cross-sectional view of a package component 100 including one or more capacitors 146 therein, in accordance with some embodiments. The capacitors 146 may be Metal-Insulator-Metal (MIM) capacitors or the like, in some embodiments. The package component 100 may be, for example, a device wafer, an interposer wafer, a package (e.g., an Integrated Fan-Out (InFO) package or the like), or the like. In the subsequently illustrated embodiments, a device wafer is used as an example structure for the package component 100, but capacitors 146 may be formed in other structures or in other regions of a device wafer, such as in a back-end redistribution structure of a device wafer. Accordingly, one of ordinary skill in the art should appreciate that the formation of the capacitors 146 as described herein is not limited to the examples shown and described in the present disclosure. FIG. 1 shows three example capacitors 146A, 146B, and 146C, and for simplicity “capacitor 146” as used herein may refer to any or all of the capacitors 146A-C or to other capacitors 146 not explicitly shown in FIG. 1.

Referring to FIG. 1, package component 100 includes a substrate 110, in accordance with some embodiments. The substrate 110 may be a semiconductor substrate, such as a bulk semiconductor, a semiconductor-on-insulator (SOI) substrate, or the like, which may be doped (e.g., with a p-type or an n-type dopant) or undoped. The substrate 110 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. The substrate 110 is, in one alternative embodiment, based on an insulating core such as a fiberglass reinforced resin core or organic core. The insulating core may comprise materials such as fiberglass resin, bismaleimide-triazine (BT) resin, printed circuit board (PCB) materials or films, build-up films such as Ajinomoto build-up film (ABF), other laminates, the like, or a combination thereof.

Devices 112 may be formed at or near a surface of the substrate 110, in accordance with some embodiments. The devices 112 may be integrated circuit devices and may include active devices (e.g., transistors, diodes, or the like) and/or passive devices (e.g., capacitors, resistors, or the like). The transistors may be, for example, planar Field-Effect Transistors (FETs), Fin Field-Effect Transistors (FinFETs), Nanostructure Field-Effect Transistors (NSFETs, nanosheet FETs, etc.), or the like. The transistors may include n-type transistors (e.g., NFETs) and/or p-type transistors (e.g., PFETS). Other devices or combinations of devices are possible.

The package component 100 may further include an Inter-Layer Dielectric (ILD) 114 and an interconnect structure 116 over the substrate 110, in accordance with some embodiments. The ILD 114 may surround and/or cover the devices 112, in some cases. The ILD 114 may include one or more dielectric layers formed of materials such as silicon nitride, silicon oxide, Phospho-Silicate Glass (PSG), Boro-Silicate Glass (BSG), Boron-Doped Phospho-Silicate Glass (BPSG), undoped Silicate Glass (USG), the like, or a combination thereof.

The interconnect structure 116 includes conductive features such as metallization patterns, redistribution layers, or the like formed in one or more dielectric layers 118, in some embodiments. One or more of the dielectric layers 118 may be Inter-Metal Dielectric (IMD) layers, in some cases. The interconnect structure 116 may be electrically connected to the devices 112 to form functional circuits. In some embodiments, the functional circuits formed by the interconnect structure 116 may comprise logic circuits, memory circuits, sense amplifiers, controllers, input/output circuits, image sensor circuits, the like, or a combination thereof.

The dielectric layers 118 may comprise one or more layers of one or more suitable dielectric materials, such as silicon oxide, PSG, BSG, BPSG, USG, a low dielectric constant (low-k) material, fluorosilicate glass (FSG), silicon oxycarbide, carbon-doped oxide (CDO), flowable oxide, a polymer, the like, or a combination thereof. In some cases, the material of one or more dielectric layers 118 may be similar to the material of the ILD 114. The dielectric layers 118 may be deposited using any suitable technique, such as Chemical Vapor Deposition (CVD), Physical Vapor Deposition (PVD), Atomic Layer Deposition (ALD), Plasma-Enhanced ALD (PEALD), Plasma-Enhanced CVD (PECVD), Flowable CVD (FCVD), spin-on, the like, or a combination thereof. Other materials or formation techniques are possible.

The conductive features of the interconnect structure 116 may comprise, for example, conductive lines 120, conductive vias 122, conductive pads 128, or the like. In some embodiments, the conductive pads 128 are formed in a top dielectric layer 118 of the interconnect structure 116. The interconnect structure 116 shown in FIG. 1 is an example, and it should be appreciated that the interconnect structure 116 may include any number of dielectric layers 118 having various conductive features disposed therein. In some embodiments, the interconnect structure 116 may be formed as part of a Back End of Line (BEOL) process or a Middle End of Line (MEOL) process. The conductive features may be formed using a suitable technique such as damascene, dual damascene, or another technique. In some embodiments, the conductive features may comprise a liner (not shown), such as a diffusion barrier layer, an adhesion layer, or the like, and a conductive material. The liner may include titanium, titanium nitride, tantalum, tantalum nitride, the like, or a combination thereof. The conductive material may include copper, a copper alloy, silver, gold, tungsten, cobalt, aluminum, nickel, ruthenium, the like, or a combination thereof. The material(s) of the conductive features may be deposited using a suitable technique such as ALD, CVD, PVD, plating, electro-less plating, the like, or a combination thereof. Other materials or formation techniques are possible.

In some embodiments, metal pads 130 are formed over and electrically coupled to the interconnect structure 116. The metal pads 130 may be electrically coupled to the devices 112 through the conductive pads 128, conductive lines 120, and vias 122 of the interconnect structure 116. The metal pads 130 may be, for example, aluminum pads or aluminum-copper pads, though other materials are possible. In accordance with some embodiments, the metal pads 130 are in physical contact with underlying conductive features of the interconnect structure 116, which may include the topmost conductive features of the interconnect structure 116. For example, as shown in FIG. 1, the metal pads 130 have bottom surfaces that are in physical and electrical contact with top surfaces of conductive pads 128.

As also shown in FIG. 1, a passivation layer 132 may be formed over the interconnect structure 116, in some embodiments. In some embodiments, the passivation layer 132 is formed on conductive pads 128 and on the top dielectric layer 118 of the interconnect structure 116. The passivation layer 132 may comprise one or more layers of dielectric materials such as USG, silicon oxide, silicon nitride, silicon oxynitride, non-porous dielectric materials, low-k dielectric materials, the like, or a combination thereof. Other materials or combinations of materials are possible. The passivation layer 132 may be formed using one or more suitable techniques. The passivation layer 132 is patterned, such that central portions of the metal pads 130 are exposed. In some embodiments, edge portions of the metal pads 130 may remain covered by the passivation layer 132. In some embodiments, some top surfaces of the passivation layer 132 and the metal pads 130 are level.

In some embodiments, a dielectric layer 136 is formed over the metal pads 130 and the passivation layer 132. In some embodiments, the dielectric layer 136 is formed of one or more polymer materials such as polybenzoxazole (PBO), polyimide, benzocyclobutene (BCB), or the like. A polymer material of the dielectric layer 136 may be photosensitive, in some cases. In alternative embodiments, the dielectric layer 136 may be formed of one or more materials such as silicon oxide, silicon nitride, PSG, BSG, BPSG, the like, or a combination thereof. The dielectric layer 136 may be formed, for example, by spin coating, lamination, CVD, or the like. Other materials or techniques are possible.

In some embodiments, a Post-Passivation Interconnect (PPI) 138 may formed over the dielectric layer 136, The PPI 138 may include, for example, conductive line portions over a top surface of the dielectric layer 136 and/or conductive via portions extending into the dielectric layer 136. The PPI 138 may be electrically connected to the metal pads 130, in some embodiments. The PPI 138 may be formed of one or more conductive materials such as copper, a copper alloy, titanium, tungsten, aluminum, or the like. Other materials are possible.

A dielectric layer 142 may be formed over the dielectric layer 136 and the PPI 138, in some embodiments. The dielectric layer 142 may be formed of one or more materials similar to those described previously for the dielectric layer 136. The dielectric layer 136 and the dielectric layer 142 may be formed of the same material(s) or may be formed of different materials.

In some embodiments, a PPI 150 is formed over the dielectric layer 142. The PPI 150 may be electrically connected to the PPI 138 and thus to the devices 112. The PPI 150 may include conductive features such as redistribution lines, metal pads, Under-Bump Metallizations (UBMs), or the like. In accordance with some embodiments, a dielectric layer 152 may be formed over the PPI 150. The dielectric layer 152 may cover and/or encircle the conductive features of the PPI 150, and the dielectric layer 152 may physically contact a top surface of the dielectric layer 142. The dielectric layer 152 may be formed of one or more materials similar to those described previously for the dielectric layer 136, or may be formed of another material such as a molding compound, an encapsulant, or the like. Other materials are possible.

In accordance with some embodiments, conductive connectors 154 are formed on the PPI 150. The conductive connectors 154 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 154 may include a conductive material such as solder, copper, aluminum, gold, nickel, silver, palladium, tin, the like, or a combination thereof. In some embodiments, the conductive connectors 154 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 154 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. The conductive connectors 154 may be encircled or embedded in the dielectric layer 152, in some embodiments. The conductive connectors 154 may be formed before or after deposition of the dielectric layer 152. In some embodiments, a singulation process (e.g., a sawing process or the like) may be performed to singulate the structure into individual package components 100 that each comprise at least one capacitor 146. In some embodiments, the singulated package components 100 are device dies or the like. The singulation process may be performed before or after formation of the conductive connectors 154.

In accordance with some embodiments, the package component 100 includes one or more capacitors 146. As described previously, the capacitors 146 are represented in FIG. 1 by capacitors 146A, 146B, and/or 146C. The capacitors 146 may be formed in one or more dielectric layers of the package component 100, such as the dielectric layers 118 of the interconnect structure 116 or the dielectric layers 136/142. In this manner, the capacitors 146 may be formed as part of a MEOL process and/or a BEOL process. The capacitor 146A represents a capacitor 146 formed in an upper dielectric layer 118 of the interconnect structure 116, such as a dielectric layer 118 at or near the top of the interconnect structure 116. The capacitor 146A may be formed underneath the passivation layer 132, as shown in FIG. 1. The capacitor 146A is electrically coupled to the conductive pads 128, in some embodiments. The capacitor 146B represents a capacitor 146 formed in one or more dielectric layers 118 within the interconnect structure 116. For example, the capacitor 146B may be formed at or near the bottom or the middle of the interconnect structure 116. The capacitor 146B is electrically coupled to conductive lines 120 or vias 122 of the interconnect structure 116, in some embodiments. The capacitor 146C represents a capacitor 146 formed over the passivation layer 132, such as in the dielectric layer 136 and/or the dielectric layer 142. In some embodiments, the dielectric layer 136 and/or 142 may be a polymer layer, as described previously. The capacitor 146C is electrically coupled to the PPI 138 and/or the PPI 150, in some embodiments.

In some embodiments, a capacitor 146 is electrically coupled to other features of a package component by vias or contact plugs that physically and electrically contact the top electrode(s) and the bottom electrode(s) of the capacitor 146. In some embodiments, a capacitor 146 is a decoupling capacitor, in which the top electrode(s) and the bottom electrode(s) of the capacitor 46 are electrically coupled to power supply lines such as VDD and VSS. In this manner, a capacitor 146 may be used to filter or suppress power supply noise and/or may be used to reduce the effect of voltage variation from the power source. In accordance with alternative embodiments of the present disclosure, the top electrode(s) and the bottom electrode(s) of a capacitor 146 are connected to signal lines, and the capacitor 146 is used to filter or suppress signal line noise. In other embodiments, a capacitor 146 as described herein may be used in other structures or for other purposes. As a non-limiting example, a capacitor 146 may be used in Dynamic Random-Access Memory (DRAM) cells. Other structures or devices having capacitors 146 as described herein are possible.

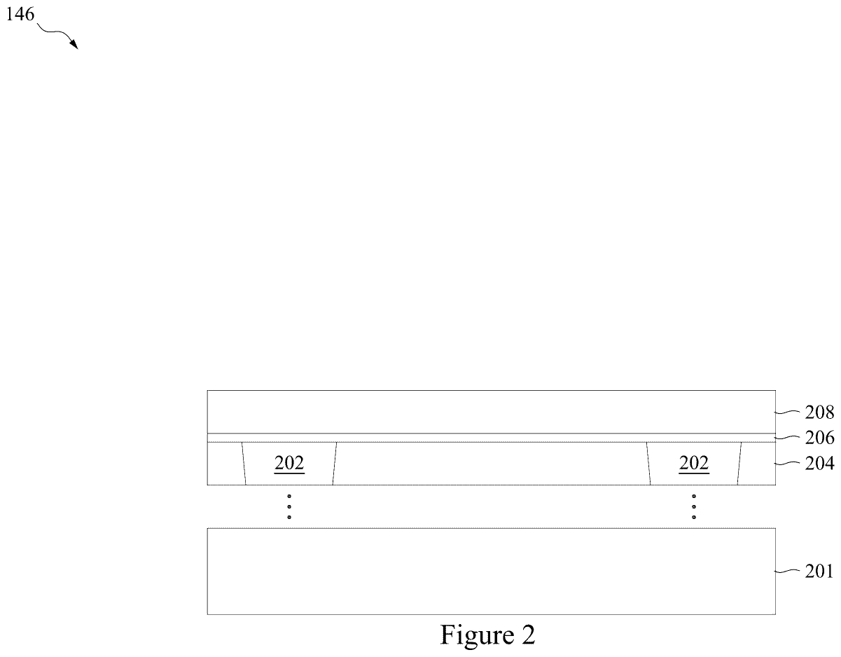

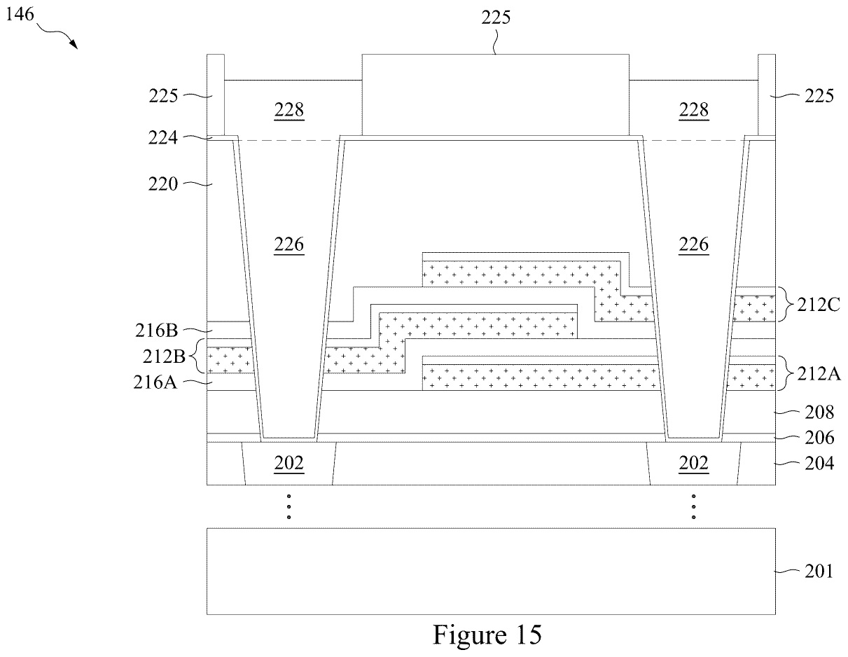

FIGS. 2 through 16 illustrate cross-sectional views of intermediate stages in the formation of a capacitor 146 (see FIG. 15), in accordance with some embodiments. The process of FIGS. 2-16 is shown in a context similar to that of forming a capacitor 146A of FIG. 1, but it should be appreciated that the techniques described herein may be applied to the formation of a capacitor 146B, a capacitor 146C, or other capacitors formed in other layers. In this manner, the cross-sectional views of FIGS. 2-16 may correspond to magnified views of a portion of the package component 100 of FIG. 1, such as a portion of the interconnect structure 116.

The capacitor 146 shown in FIG. 15 comprises alternating layers of electrodes 212 (individually indicated as electrodes 212A, 212B, and 212C) and layers of insulators 216 (individually indicated as insulators 216A and 216B). For example, the embodiment shown in FIG. 15 includes a first electrode 212A (e.g., a “bottom electrode 212A”), a second electrode 212B (e.g., a “middle electrode 212B”), and a third electrode 212C (e.g., a “top electrode 212C”). The embodiment in FIG. 15 also includes a first insulator 216A (e.g., a “bottom insulator 216A”) and a second insulator 216B (e.g., a “top insulator 216B”). As used in the present disclosure, the term “electrode(s) 212” may refer to any or all of the electrodes 212A-C, and the term “insulator(s) 216” may refer to any or all of the insulators 216A-B. The capacitor 146 shown in FIGS. 1-16 is an example, and other capacitors 146 having a different configuration, a different layout, a different number of various layers (e.g., electrodes 212 and/or insulators 216), or a different arrangement of features are possible.

In some embodiments, each electrode 212 comprises an upper electrode layer 211 over a lower electrode layer 210. For example, the first electrode 212A comprises a first upper electrode layer 211A over a first lower electrode layer 210A, the second electrode 212B comprises a second upper electrode layer 211B over a second lower electrode layer 210B, and the third electrode 212C comprises a third upper electrode layer 211C over a third lower electrode layer 210C. As used in the present disclosure, the term “upper electrode layer(s) 211” may refer to any or all of the upper electrode layers 211A-C, and the term “lower electrode layer(s) 210” may refer to any or all of the lower electrode layers 210A-C. In this manner, an electrode 212 may be considered a bi-layer. The upper electrode layer 211 and the lower electrode layer 210 may comprise the same material, in some embodiments. The upper electrode layers 211A-C and the lower electrode layers 210A-C are described in greater detail below.

Referring to FIG. 2, conductive features 202 in a dielectric layer 204 are illustrated, in accordance with some embodiments. In some embodiments, the conductive features 202 may be similar to conductive features of the interconnect structure 116, such as conductive lines 120, vias 122, or conductive pads 128. In other embodiments, the conductive features 202 may be similar to other features, such as the metal pads 130, the PPI 138, the PPI 150, or the like. The conductive features 202 may be formed within a dielectric layer 204, which may be similar to a dielectric layer 118 of the interconnect structure 116, in some embodiments. For example, the dielectric layer 204 may comprise silicon oxide, silicon nitride, or the like. In other embodiments, the dielectric layer 204 may be similar to another dielectric layer, such as the dielectric layer 136, the dielectric layer 142, or the like. For example, in some embodiments, the dielectric layer 204 may comprise a polymer. Other materials are possible. The portions of the package component 100 underlying conductive features 202 are represented as features 201. The details of features 201 are not illustrated, and may be similar to features described previously for FIG. 1. For example, the features 201 may include or represent conductive features, active devices, passive devices, the like, or a combination thereof.

An etch stop layer 206 and a dielectric layer 208 are formed over the conductive features 202 and the dielectric layer 204, in accordance with some embodiments. The etch stop layer 206 is an optional layer, and may comprise one or more layers of dielectric material that have a lower etch rate than the underlying dielectric layer 204 and/or the overlying dielectric layer 208, in some cases. In some embodiments, the etch stop layer 206 may comprise one or more layers of material such as silicon nitride, silicon oxide, silicon oxynitride, silicon carbide, silicon carbonitride, silicon oxycarbide, the like, or a combination thereof. The etch stop layer 206 may be formed using a suitable technique, such as CVD, PECVD, LPCVD, PVD, ALD, or the like. Other materials or formation techniques are possible.

The dielectric layer 208 may be formed of material(s) similar to those described previously for the dielectric layer 204, the dielectric layers 118, or the dielectric layers 136/142, and may be formed using similar techniques. For example, in some embodiments, the dielectric layer 208 comprises silicon nitride, silicon oxide, silicon oxynitride, or the like. Other materials are possible. The dielectric layer 208 may be the same material as the underlying dielectric layer 204 or may be a different material.

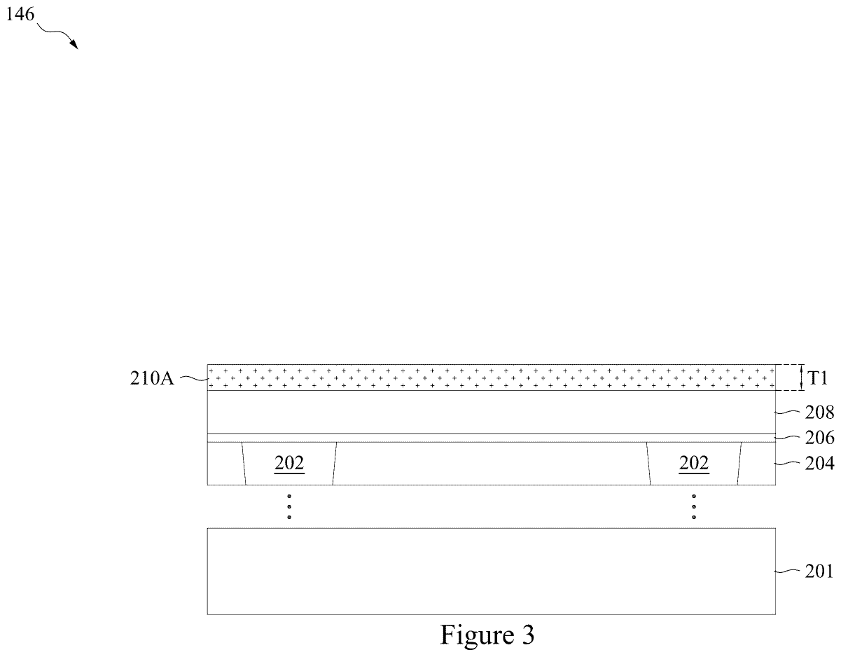

In FIG. 3, a first lower electrode layer 210A is deposited over the dielectric layer 208, in accordance with some embodiments. In some embodiments, before depositing the first lower electrode layer 210A, the dielectric layer 208 is thinned using a planarization process such as a Chemical-Mechanical Polishing (CMP) process or the like. The first lower electrode layer 210A may be formed of one or more conductive materials such as titanium nitride, tantalum nitride, another metal nitride, titanium, tungsten, platinum, iridium, ruthenium, ruthenium oxide (e.g., RuO₂), a combination thereof, or the like. In some embodiments, the first lower electrode layer 210A is formed of layers of different materials, such as two or more layers comprising titanium nitride, tantalum nitride, titanium, tungsten or the like. For example, in some embodiments, the first lower electrode layer 210A includes a layer of titanium or tungsten over a layer of titanium nitride or tantalum nitride. Other combinations of layers or materials are possible.

The first lower electrode layer 210A may be deposited as a blanket layer, and may be deposited using a suitable technique such as PVD or the like. In some embodiments, the first lower electrode layer 210A is deposited using a PVD process having a process temperature in the range of about 250° C. to about 350° C., a process pressure in the range of about 10 mTorr to about 250 mTorr, or a bias power in the range of about 50 W to about 80 W. Other process conditions are possible. For example, in some embodiments, the first lower electrode layer 210A is a layer of titanium nitride deposited using a PVD process. In some embodiments, the deposited layer of titanium nitride has a density in the range of about 5 g/cm³ to about 6 g/cm³, an electrical resistivity in the range of about 80 Ω·m to about 110 Ω·m, and a ratio of (200) crystalline orientation to (111) crystalline orientation that is in the range of about 6:1 to about 7:1. However, other material properties are possible, and other materials are possible. In some embodiments, the first lower electrode layer 210A may have a thickness T1 in the range of about 450 Å to about 570 Å, though other thicknesses are possible.

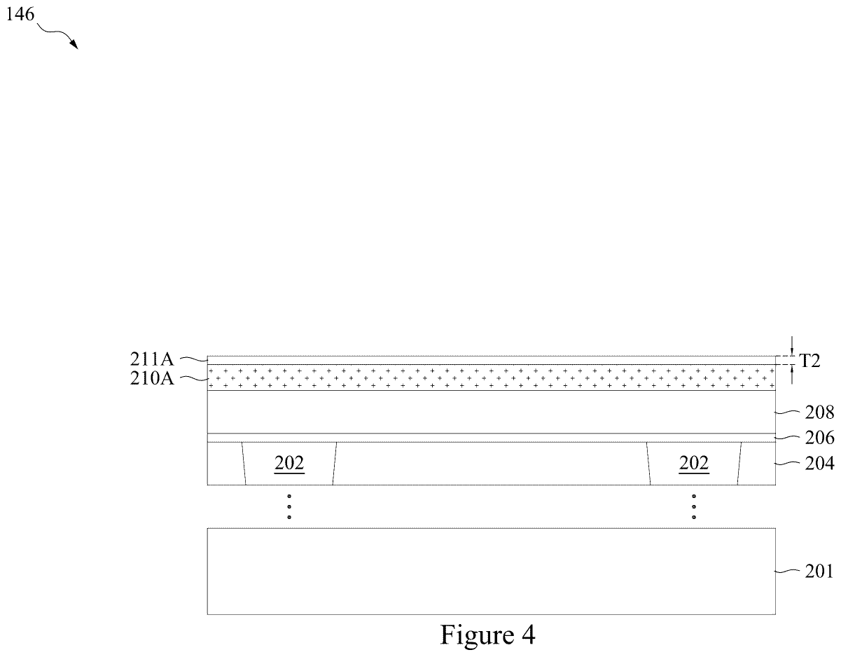

In FIG. 4, a first upper electrode layer 211A is deposited over the first lower electrode layer 210A, in accordance with some embodiments. A first electrode 212A is subsequently formed as a bi-layer of the first upper electrode layer 211A and the first lower electrode layer 210A, described in greater detail below. The first upper electrode layer 211A may be formed of one or more conductive materials similar to those described previously for the first lower electrode layer 210A. For example, in some embodiments, the first upper electrode layer 211A may be a material such as titanium nitride, tantalum nitride, another metal nitride, or the like. In some embodiments, the first upper electrode layer 211A is formed of a material that is the same as or similar to the material of the underlying first lower electrode layer 210A. For example, in some embodiments, the first upper electrode layer 211A and the first lower electrode layer 210A are both titanium nitride, though other materials are possible. In embodiments in which the first lower electrode layer 210A is formed of two or more layers of different materials, the first upper electrode layer 211A may be formed of one of the materials of the first lower electrode layer 210A, in some cases. For example, for embodiments in which the first lower electrode layer 210A includes a layer of titanium or tungsten over a layer of titanium nitride or tantalum nitride, the first upper electrode layer 211A may be a layer of titanium nitride or tantalum nitride, respectively. Other combinations of layers or materials are possible. In other embodiments, the first upper electrode layer 211A and the first lower electrode layer 210A may be different materials or may have different compositions of materials.

In some embodiments, the first upper electrode layer 211A may be deposited as a blanket layer, and may be deposited using a suitable technique such as ALD or the like. In some embodiments, the first upper electrode layer 211A is deposited using a different deposition technique than the underlying first lower electrode layer 210A. For example, in some embodiments, the first lower electrode layer 210A is a material deposited using a PVD process and the first upper electrode layer 211A is the same material deposited using an ALD process. For example, in some embodiments, the first lower electrode layer 210A is a titanium nitride layer deposited using a PVD process, and the first upper electrode layer 211A is a titanium nitride layer deposited using an ALD process. Other materials or deposition techniques are possible. In some cases, depositing the electrode 212 material as a bi-layer using two deposition processes can improve reliability of the capacitor 146, described in greater detail below.

In some embodiments, the first upper electrode layer 211A is deposited using an ALD process having a process temperature in the range of about 300° C. to about 400° C., though other process conditions are possible. For example, in some embodiments, the first upper electrode layer 211A is a layer of titanium nitride deposited using an ALD process. In some embodiments, the deposited layer of titanium nitride has a density in the range of about 4 g/cm³ to about 5 g/cm³, an electrical resistivity in the range of about 800 Ω·m to about 900 Ω·m, and a ratio of (200) crystalline orientation to (111) crystalline orientation that is in the range of about 1:1 to about 1.5:1. However, other material properties are possible, and other materials are possible. The first upper electrode layer 211A may have a thickness T2 that is less than a thickness T1 of the first lower electrode layer 210A. In some embodiments, the first upper electrode layer 211A may have a thickness T2 in the range of about 30 Å to about 50 Å, though other thicknesses are possible. In some cases, a thickness T2 in the range of about 30-50 Å can protect the first lower electrode layer 210A and the first upper electrode layer 211A from damage during a subsequent high-pressure anneal (HPA) process, described in greater detail below. In this manner, the reliability window of bi-layer electrodes (e.g., electrodes 212A-C, described below) may be increased.

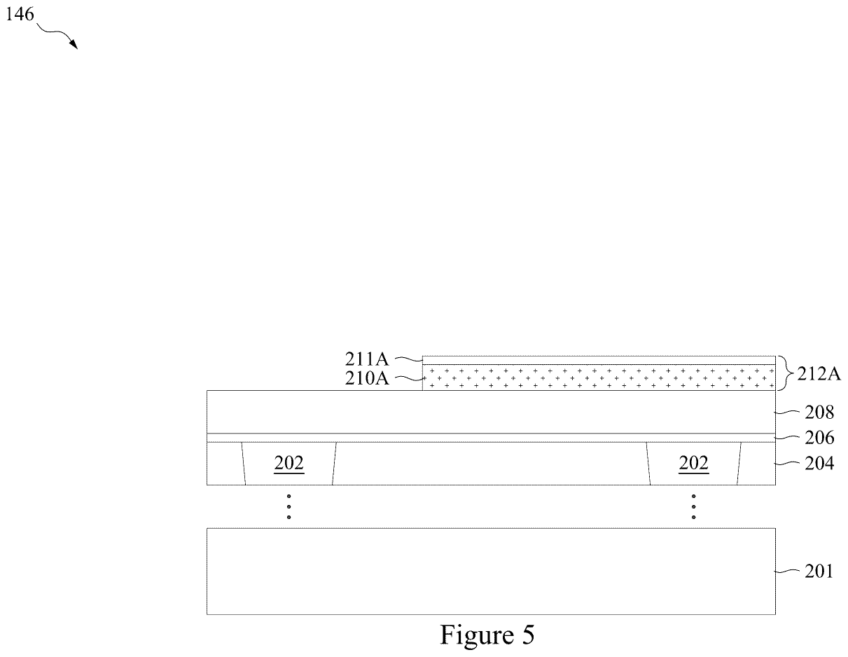

In FIG. 5, the first lower electrode layer 210A and the first upper electrode layer 211A are patterned to form the first electrode 212A, in accordance with some embodiments. The first lower electrode layer 210A and the first upper electrode layer 211A may be patterned using suitable photolithography and etching techniques. For example, an etching mask (not illustrated) may be formed over the first upper electrode layer 211A. The etching mask may be formed, for example, by forming a mask layer over the first upper electrode layer 211A and then patterning the mask layer. The mask layer may be, for example, a photoresist, a multi-layer photoresist structure, a hard mask material, or the like. The mask layer may be patterned using suitable photolithographic techniques to form the etching mask. The pattern of the etching mask corresponds to the pattern of the subsequently formed first electrode 212A.

The first lower electrode layer 210A and the first upper electrode layer 211A are then etched using the etching mask to form the first electrode 212A, in accordance with some embodiments. In other embodiments, two or more first electrodes 212A may be formed from the first lower electrode layer 210A and the first upper electrode layer 211A. The etching may include any acceptable etching process, such as a wet etching process, a dry etching process, a reactive ion etch (RIE), neutral beam etch (NBE), the like, or a combination thereof. The etching may be anisotropic. The etching may etch through both the first lower electrode layer 210A and the first upper electrode layer 211A and stop on the dielectric layer 208, in some cases. The etching may expose top surfaces of the dielectric layer 208. After patterning the first lower electrode layer 210A and the first upper electrode layer 211A to form the first electrode 212A, the etching mask may be removed using an acceptable process, such as an ashing process or the like.

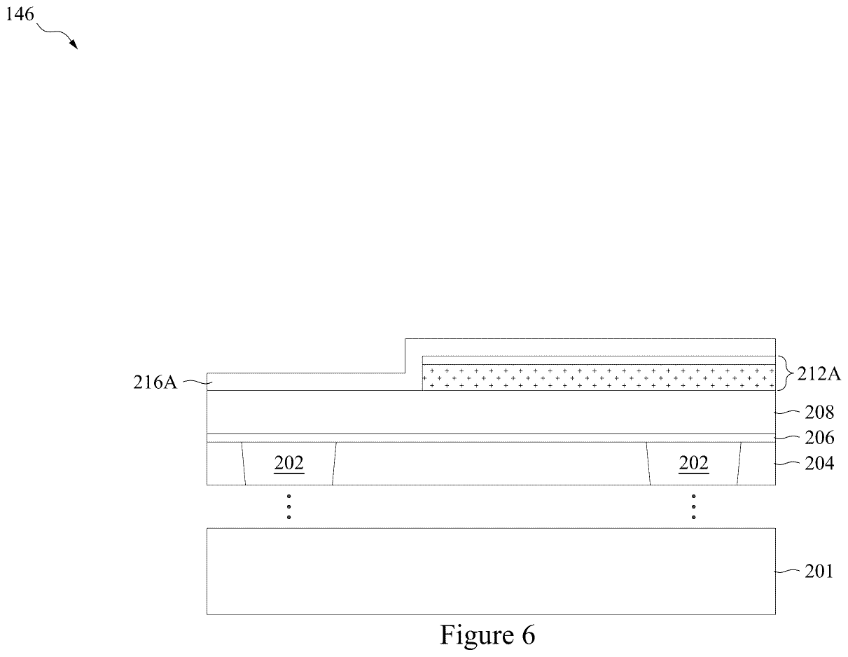

FIG. 6 illustrates the formation of a first insulator 216A over the first electrode 212A, in accordance with some embodiments. The first insulator 216A may comprise one or more insulating materials having a high dielectric constant (e.g., high-k) to achieve larger capacitance values of the resulting capacitor 146. For example, in some embodiments, the first insulator 216A may comprise hafnium oxide (e.g., HfO₂), zirconium oxide (e.g., ZrO₂, ZrO₃, or the like), hafnium zirconium oxide (e.g., HfZrO), aluminum oxide (e.g., Al₂O₃), the like, a combination thereof, or multilayers thereof. The first insulator 216A may be deposited as a conformal layer (e.g., a blanket layer) using a suitable technique, such as ALD, CVD, or the like. Accordingly, in some embodiments, the first insulator 216A is deposited on top surfaces of the first electrode 212A and on top surfaces of the dielectric layer 208.

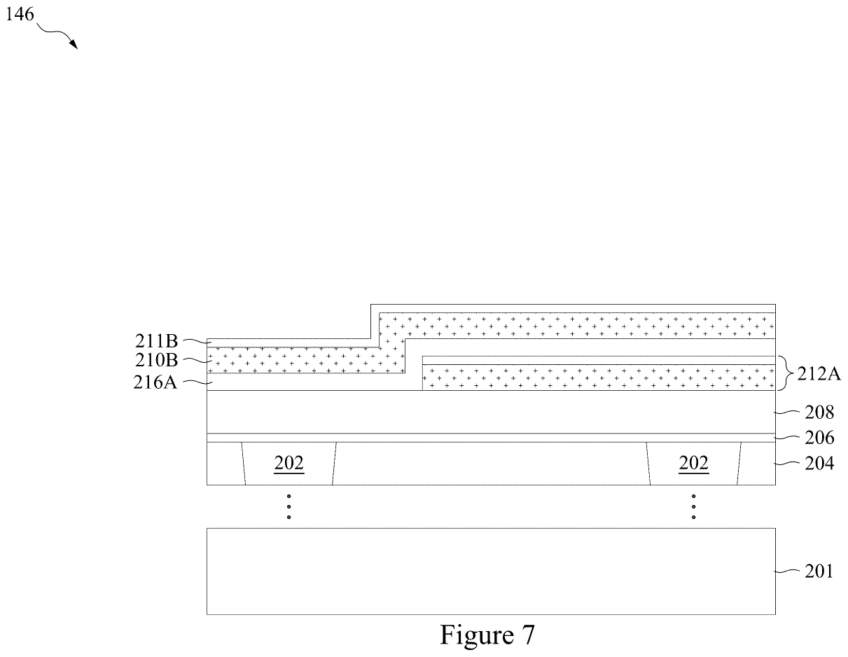

In FIG. 7, a second lower electrode layer 210B and a second upper electrode layer 211B are formed over the first insulator 216A, in accordance with some embodiments. The second lower electrode layer 210B may be similar to the first lower electrode layer 210A, and may be formed using similar materials or techniques. The second upper electrode layer 211B may be similar to the first upper electrode layer 211A, and may be formed using similar materials or techniques. In some embodiments, the second lower electrode layer 210B and the second upper electrode layer 211B may be the same material formed using different deposition techniques, similar to the first lower electrode layer 210A and the first upper electrode layer 211A. For example, in some embodiments, the second lower electrode layer 210B may be titanium nitride formed using a PVD process, and the second upper electrode layer 211B may be titanium nitride formed using an ALD process. In other embodiments, the second lower electrode layer 210B may include two or more layers of different materials. Other materials or deposition techniques are possible.

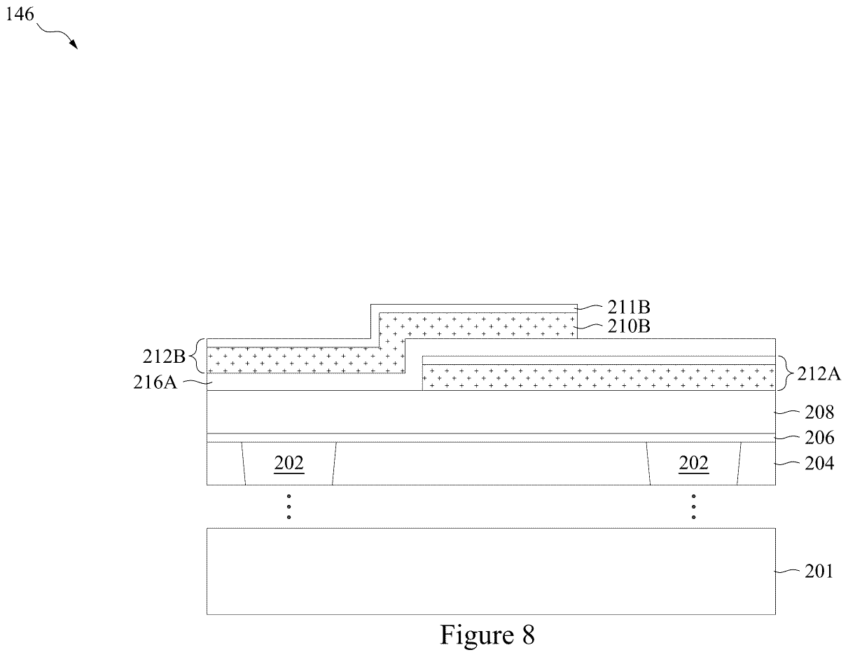

In FIG. 8, the second lower electrode layer 210B and the second upper electrode layer 211B are patterned to form the second electrode 212B, in accordance with some embodiments. The second lower electrode layer 210B and the second upper electrode layer 211B may be patterned using suitable photolithography and etching techniques. In other embodiments, two or more second electrodes 212B may be formed from the second lower electrode layer 210B and the second upper electrode layer 211B. Patterning the second lower electrode layer 210B and the second upper electrode layer 211B may expose top surfaces of the first insulator 216A.

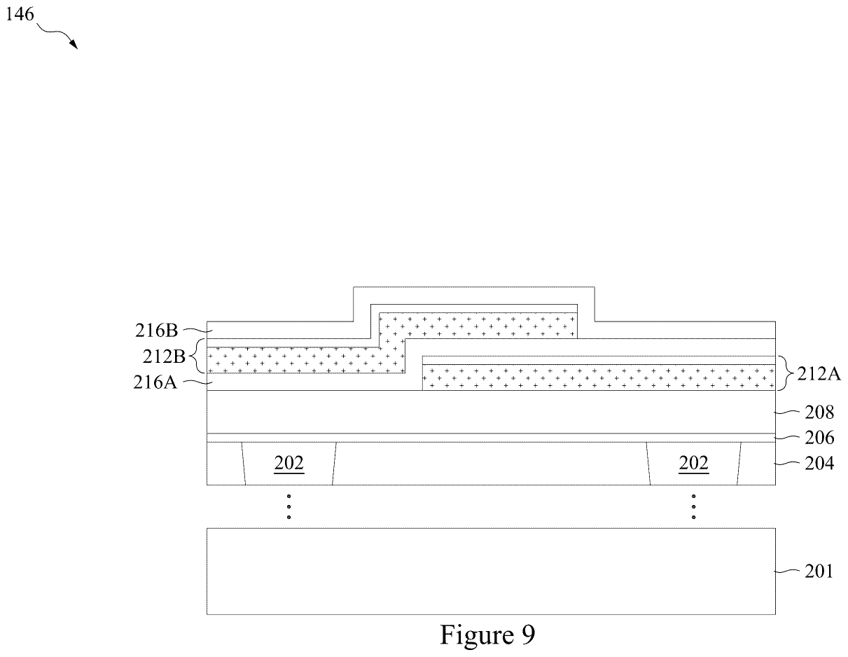

In FIG. 9, a second insulator 216B is formed over the second electrode 212B and the first insulator 216A, in accordance with some embodiments. The second insulator 216B may be similar to the first insulator 216A, and may be formed using similar materials or techniques. For example, the second insulator 216B may comprise one or more materials having a high dielectric constant (e.g., high-k), and may be formed using a conformal deposition technique.

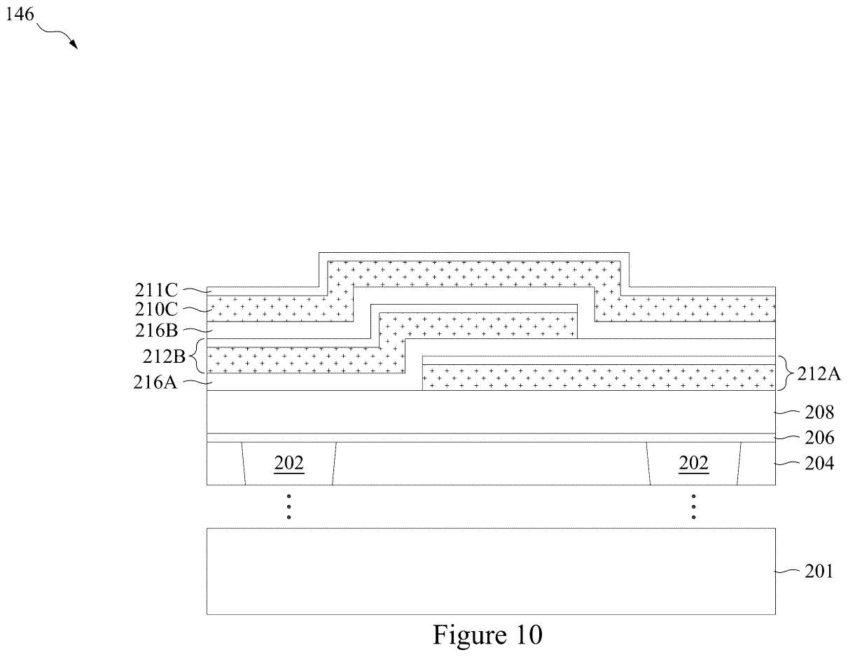

In FIG. 10, a third lower electrode layer 210C and a third upper electrode layer 211C are formed over the second insulator 216B, in accordance with some embodiments. The third lower electrode layer 210C may be similar to the first lower electrode layer 210A and/or the second lower electrode layer 210B, and may be formed using similar materials or techniques. The third upper electrode layer 211C may be similar to the first upper electrode layer 211A and/or the second upper electrode layer 211B, and may be formed using similar materials or techniques. In some embodiments, the third lower electrode layer 210C and the third upper electrode layer 211C may be the same material formed using different deposition techniques, similar to the first lower electrode layer 210A and the first upper electrode layer 211A. For example, in some embodiments, the third lower electrode layer 210C may be titanium nitride formed using a PVD process, and the third upper electrode layer 211C may be titanium nitride formed using an ALD process. In other embodiments, the third lower electrode layer 210C may include two or more layers of different materials. Other materials or deposition techniques are possible.

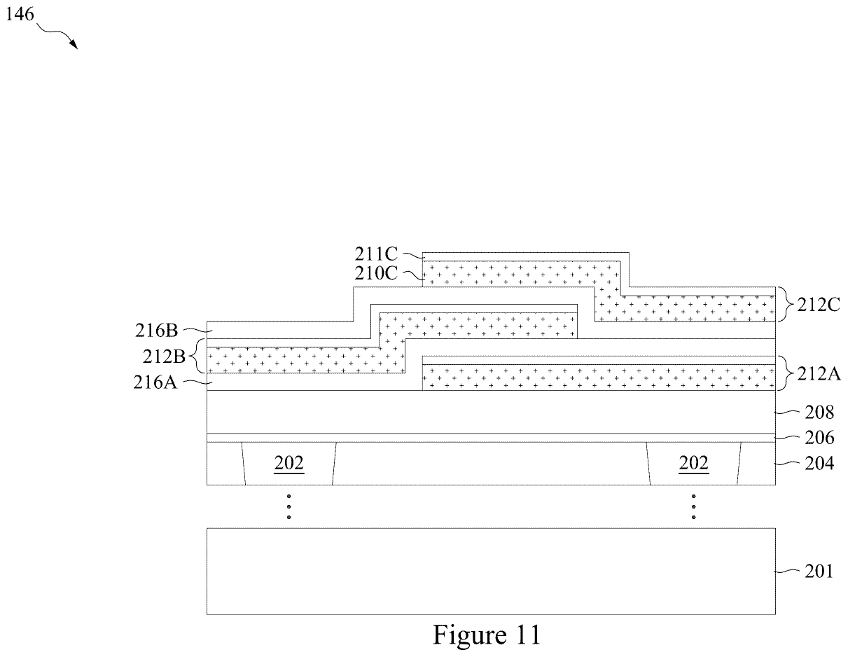

In FIG. 11, the third lower electrode layer 210C and the third upper electrode layer 211C are patterned to form the third electrode 212C, in accordance with some embodiments. The third lower electrode layer 210C and the third upper electrode layer 211C may be patterned using suitable photolithography and etching techniques. In other embodiments, two or more third electrodes 212C may be formed from the third lower electrode layer 210C and the third upper electrode layer 211C. Patterning third lower electrode layer 210C and the third upper electrode layer 211C may expose top surfaces of the second insulator 216B. In other embodiments, additional insulator layers and/or additional electrode layers may be deposited, which may be similar to the materials or deposition techniques described above for the electrodes 212A-C or the insulators 216A-B.

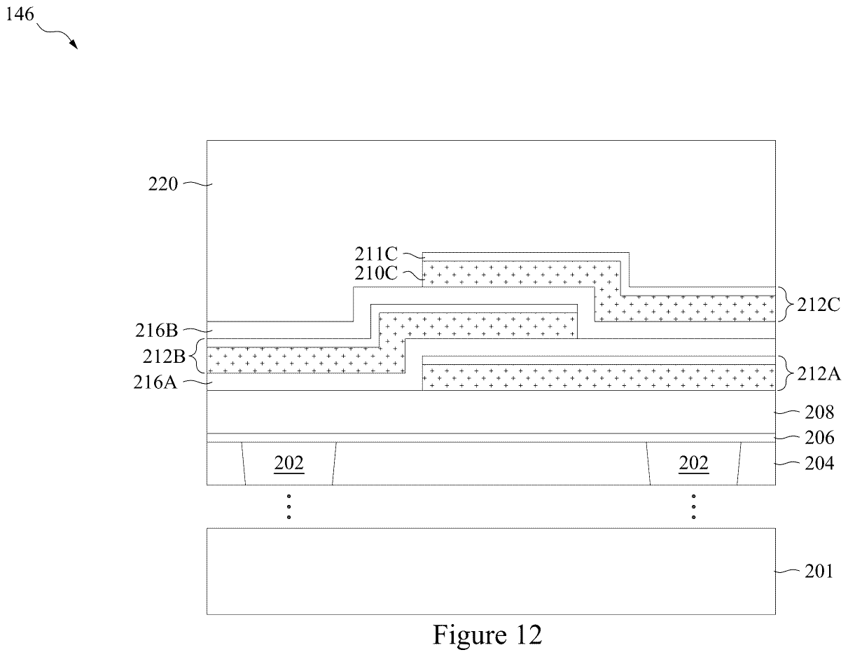

In FIG. 12, a dielectric layer 220 is deposited over the third electrode 212C and the second insulator 216B, in accordance with some embodiments. The dielectric layer 220 may be formed of material(s) similar to those described previously for the dielectric layer 204, the dielectric layers 118, or the dielectric layers 136/142, and may be formed using similar techniques. For example, in some embodiments, the dielectric layer 220 comprises silicon nitride, silicon oxynitride, a polymer, or the like. Other materials are possible. The dielectric layer 220 may be the same material as the dielectric layer 208 or may be a different material. In some embodiments, a planarization process, such as a CMP process or a grinding process, is performed on the dielectric layer 220.

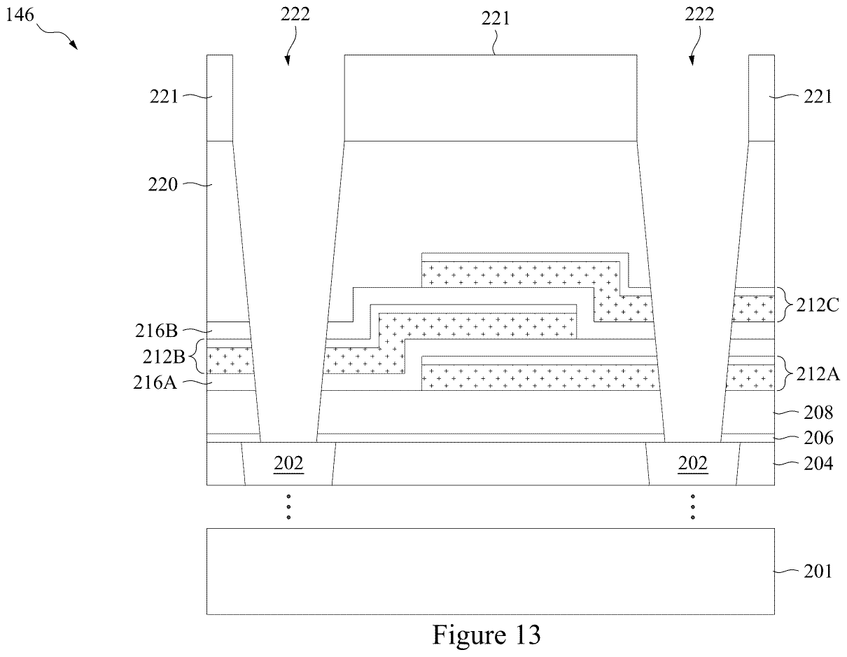

FIGS. 13, 14, and 15 illustrate cross-sectional views of intermediate steps in the formation of contact plugs 226 and conductive lines 228, in accordance with some embodiments. In FIG. 13, contact openings 222 are formed to expose surfaces of the electrodes 212A-C and surfaces of the conductive features 202, in accordance with some embodiments. In other embodiments, the openings 222 may only expose surfaces of the electrodes 212A-C without exposing surfaces of the conductive features 202. The openings 222 may be formed, for example, by performing one or more etching processes using an etching mask 221. The etching mask 221 may be, for example, a photoresist, a photoresist structure, a hard mask, or the like. The etching mask 221 may be patterned using suitable photolithography and etching techniques.

One or more etching processes may then be performed using the etching mask 221 to form openings 222 extending through the dielectric layer 220, the electrodes 212A-C, and the insulators 216A-B. The openings 222 may also extend through the dielectric layer 208 and the etch stop layer 206, in some embodiments. The openings 222 expose sidewalls of the electrodes 212A-C, and may expose top surfaces of the conductive features 202. The one or more etching processes may include wet etching processes and/or dry etching processes. One or more of the etching process es may be anisotropic. Different etching processes may be used to etch different materials, in some cases. This is an example, and other techniques or etching processes may be used for forming the openings 222 in other embodiments. After etching the openings 222, the etching mask 221 may be removed using a suitable process, such as an ashing process or an etching process.

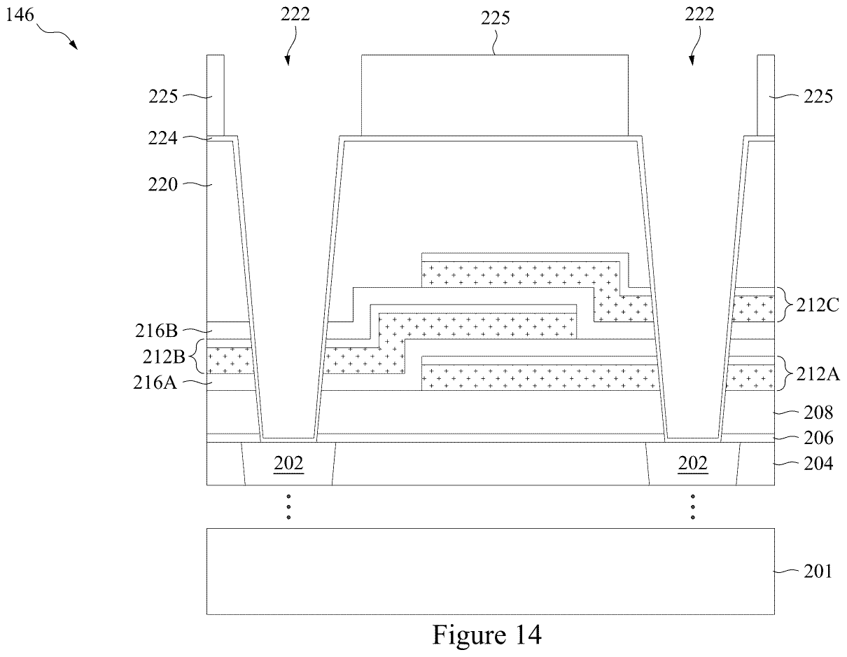

In FIG. 14, a seed layer 224 and a plating mask 225 are formed, in accordance with some embodiments. The seed layer 224 is formed over the dielectric layer 220 and in the openings 222. The seed layer 224 may make physical and electrical contact with surfaces of the electrodes 212A-C and/or the conductive features 202 that were exposed by the openings 222. In some embodiments, the seed layer 224 is a metal layer, which may be a single layer or a composite layer comprising a plurality of sub-layers formed of different materials. In some embodiments, the seed layer 224 comprises a titanium layer and a copper layer over the titanium layer, though other materials are possible. The seed layer 224 may be formed using, for example, PVD, CVD, Metal Organic Chemical Vapor Deposition (MOCVD), or the like. The plating mask 225 is then formed and patterned on the seed layer 224. The plating mask 225 may be, for example, a photoresist, a photoresist structure, a hard mask, or the like. The plating mask 225 may be patterned using suitable photolithography techniques. The pattern of the plating mask 225 may expose the seed layer 224 in and around the openings 222.

In FIG. 15, conductive material is deposited in the openings 222 to form the contact plugs 226 and the conductive lines 228, in accordance with some embodiments. The conductive material may be formed on the portions of the seed layer 224 exposed by the patterned plating mask 225. The conductive material may be formed by plating, such as electroplating or electroless plating, or the like. The conductive material may comprise a metal, such as copper, titanium, nickel, tungsten, aluminum, alloys thereof, or the like. The combination of the conductive material and underlying portions of the seed layer 224 form the contact plugs 226 and the conductive lines 228. The portions of the conductive material and seed layer 224 below a top surface of the dielectric layer 220 may be considered the contact plugs 226, and the portions of the conductive material and seed layer 224 above or along the top surface of the dielectric layer 220 may be considered the conductive lines 228. The contact plugs 226 and the conductive lines 228 may be part of continuous conductive features, in some cases. In some embodiments, the contact plugs 226 and/or the conductive lines 228 may be similar to conductive features of the interconnect structure 116 or other conductive features of the package component 100. The contact plugs 226 physically and electrically contact the conductive features 202, and the contact plugs 226 may be considered vias in some cases. The contact plugs 226 also physically and electrically contact the electrodes 212A-C. In this manner, a capacitor 146 may be formed, in accordance with some embodiments. As shown in FIG. 15, the capacitor 146 may include a stack of interdigitated electrodes 212, in which each electrode 212 is respectively separated from each neighboring electrode 212 by an insulator 216.

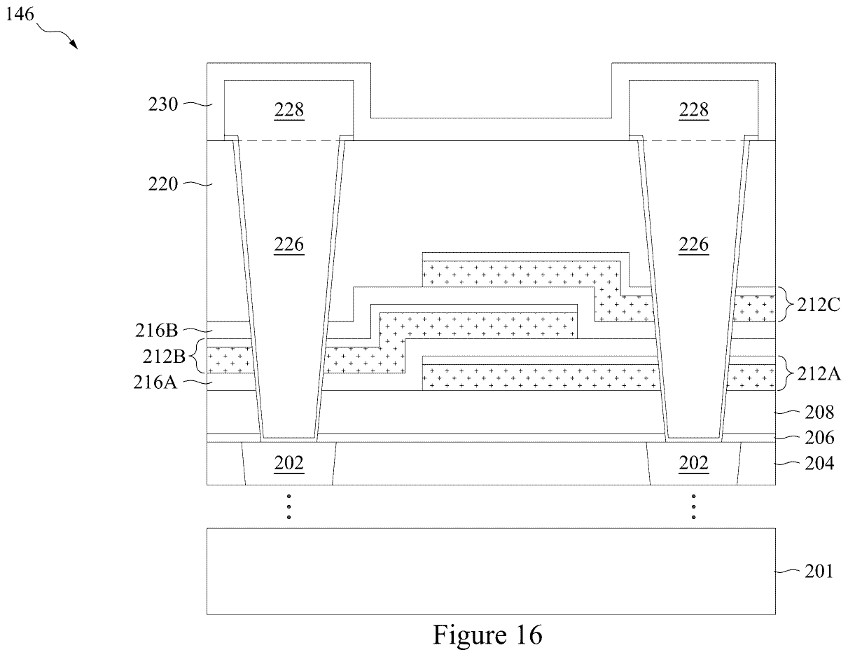

In FIG. 16, the plating mask 221 is removed and an optional passivation layer 230 is formed, in accordance with some embodiments. The plating mask 221 and underlying portions of the seed layer 224 may be removed using, for example, an ashing process and/or an etching process. The passivation layer 230 may then be deposited over the dielectric layer 220 and the conductive lines 228, in accordance with some embodiments. The passivation layer 230 may be formed of material(s) similar to those described previously for the dielectric layer 220, dielectric layer 204, the dielectric layers 118, or the dielectric layers 136/142, and may be formed using similar techniques. For example, in some embodiments, the passivation layer 230 comprises silicon oxide, silicon nitride, silicon oxynitride, silicon oxycarbide, a polymer, the like, or a combination thereof. Other materials are possible. The passivation layer 230 may be the same material as the dielectric layer 220 or may be a different material. In this manner, a capacitor 146 having bi-layer electrodes 212 may be formed, though a capacitor 146 may have a different configuration or may be formed using other manufacturing steps in other embodiments.

In some cases, a thermal process may be performed on the package component 100. The thermal process may be performed at any suitable process step, such as during formation of the capacitor(s) 146 (e.g., after any of FIGS. 11-15) or after formation of the capacitor(s) 146 (e.g., after FIG. 16 or after FIG. 1). In some cases, the thermal process may include a high-pressure anneal (HPA) process, in which the structure is annealed in a pressurized atmosphere. For example, the HPA process may be performed using a 100% hydrogen (e.g., H₂) atmosphere at a pressure between about 10 atm and about 30 atm. Other pressures or atmosphere compositions are possible. The HPA process may include a process temperature between about 350° C. and about 450° C., and may have a duration between about 15 minutes and about 60 minutes, though other process parameters are possible. In some cases, an HPA process may be performed, for example, to reduce defects in the channel region of a p-type transistor (e.g., a PFET) in the devices 112 of the package component 100. However, during an HPA process, hydrogen can replace the oxygen at or near interfaces between electrodes and insulators in a MIM capacitor. This can create oxygen vacancies at or near the electrode-insulator interface, which can severely degrade the reliability (e.g., reduce the lifetime) of the capacitor. For example, in some cases, an HPA anneal can reduce the lifetime of a capacitor to less than 1% of its expected lifetime prior to the HPA anneal.

In some cases, forming capacitor electrodes from a bi-layer of a single material as described herein can reduce the effects of an HPA process and improve the reliability of the capacitor subjected to an HPA process. As an example, in some cases, an interface between an electrode comprising titanium nitride and an insulator (e.g., insulator 216) may include oxygen bonds (e.g., Ti—O bonds) that can be disrupted or broken by hydrogen replacement during an HPA process. In other words, a capacitor may have an interfacial layer between an electrode and an insulator that comprises titanium oxynitride, and an HPA process can damage the interfacial layer. However, titanium nitride grown using ALD (e.g., “ALD TiN”) may form more oxygen bonds and/or stronger oxygen bonds with an insulator than titanium nitride grown using PVD (e.g., “PVD TiN”). The greater number and/or greater strength of the oxygen bonds formed with ALD TiN can reduce the amount of broken bonds and oxygen vacancies created by an HPA process, compared to PVD TiN. Thus, because the electrodes described herein are formed from an upper electrode layer of ALD TiN over a lower electrode layer of PVD TiN, the interface between an electrode and an overlying insulator is a relatively more robust interface between the ALD TiN of the electrode and the insulator. In other words, depositing a layer of ALD TiN can improve device reliability by improving the electrode-insulator interface. In this manner, undesirable effects in a capacitor due to thermal processes such as HPA processes can be reduced or eliminated, and the reliability window of the capacitor can be increased.

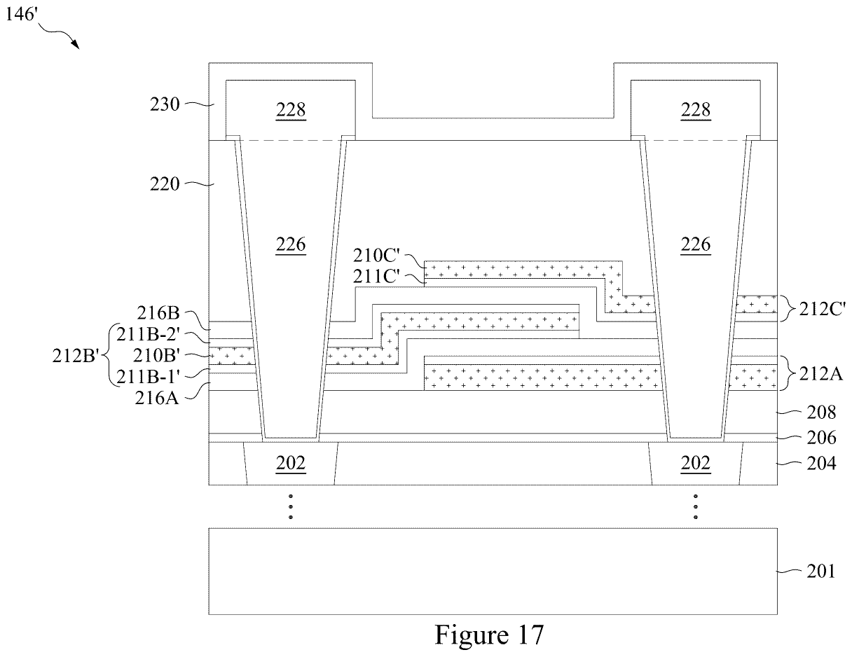

FIG. 17 illustrates a capacitor 146′comprising a tri-layer second electrode 212B′, in accordance with some embodiments. The capacitor 146′ is similar to the capacitor 146 of FIG. 16, except that the second electrode 212B′ of the capacitor 146′ includes a middle electrode layer 210B′ that is sandwiched between a lower electrode layer 211B-1′ and an upper electrode layer 211B-2′. Additionally, the third electrode 212C′ of the capacitor 146′ includes an electrode layer 210C′ over an electrode layer 211C′. The capacitor 146′ may be formed using materials or techniques similar to those of the capacitor 146 described for FIGS. 2-16, and some details may not be repeated.

In some embodiments, the capacitor 146′ is initially formed using steps similar to those described for FIGS. 1-6. For example, a first electrode 212A may be a bi-layer formed of a first upper electrode layer 211A over a first lower electrode layer 210A, and first insulator 216A over the first electrode 212A. After forming the first insulator 216A, a lower electrode layer 211B-1′ is formed over the first insulator 216A. The lower electrode layer 211B-1′ may be similar to the upper electrode layers 211 described previously for the capacitor 146. For example, the lower electrode layer 211B-1′ may be a layer of ALD titanium nitride (TiN), in some embodiments. A middle electrode layer 210B′ may then be formed over the lower electrode layer 211B-1′. The middle electrode layer 210B′ may be similar to the lower electrode layers 210 described previously for the capacitor 146. An upper electrode layer 211B-2′ is formed over the middle electrode layer 210B′. The upper electrode layer 211B-2′ may be similar to the lower electrode layer 211B-1′. The upper electrode layer 211B-2′, the middle electrode layer 210B′, and the lower electrode layer 211B-1′ may be patterned to form the second electrode 212B′. In this manner, the second electrode 212B′ may be a tri-layer electrode formed of the upper electrode layer 211B-2′, the middle electrode layer 210B′, and the lower electrode layer 211B-1′.

After forming the second electrode 212B′, a second insulator 216B is deposited. The second insulator 216B may be similar to the second insulator 216B of the capacitor 146. An electrode layer 211C′ may be deposited over the second insulator 216B. The electrode layer 211C′ may be similar to the first upper electrode layer 211A, the lower electrode layer 211B-1′, or the upper electrode layer 211B-2′. For example, the electrode layer 211C′ may be a layer of ALD titanium nitride (TiN), in some embodiments. An electrode layer 210C′ may then be formed over the electrode layer 211C′. The electrode layer 210C′ may be similar to the middle electrode layer 210B′ or the first lower electrode layer 210A. The electrode layer 211C′ and the electrode layer 210C′ may be patterned to form a bi-layer third electrode 212C′. In this manner, the first upper electrode layer 211A is at the interface between the first electrode 212A and the insulator 216A, the lower electrode layer 211B-1′ is at the interface between the second electrode 212B′ and the insulator 216A, the upper electrode layer 211B-2′ is at the interface between the second electrode 212B′ and the insulator 216B, and the electrode layer 211C′ is at the interface between the third electrode 212C′ and the insulator 216B. Thus, in some embodiments, layers of ALD TiN may be present at the interfaces between the electrodes 212A/212B′/212C′ and the insulators 216A/216B. Forming layers of ALD Til at the interfaces between electrodes 212A/212B′/212C′ and insulators 216A/216B can improve device reliability and reduce damage to the capacitor 146′ during an HPA process.

The use of ALD TiN layers as described herein can improve the reliability of a capacitor after an HPA process, according to time-dependent dielectric breakdown (TDDB) measurements. For example, some TDDB measurements suggest that the expected lifetime of a capacitor, after an HPA process, may be in the range of about 80 years to about 2500 years. This is an example from experimental results, and other reliability measures or expected lifetimes are possible. In some cases the upper layer of ALD TiN may be deposited as a thin layer on the lower layer of PVD TiN, such that the interfacial properties of an electrode are dominated by the ALD TiN but the bulk electrical properties of the electrode are dominated by the PVD TiN. While titanium nitride is used as an example for explanatory purposes, other materials, such as those described previously for the electrodes 212, may be utilized according to the teachings herein.

In an embodiment, a method includes forming a first electrode, including depositing a first layer of a conductive material; and depositing a second layer of the conductive material on the first layer of the conductive material; forming a first insulator layer on the second layer of the conductive material; and forming a second electrode, including depositing a third layer of the conductive material over the first insulator layer; and depositing a fourth layer of the conductive material over the third layer of the conductive material. In an embodiment, forming the second electrode further includes depositing a fifth layer of the conductive material over the first insulator layer. In an embodiment, the method includes annealing the first insulator layer in a hydrogen atmosphere. In an embodiment, the second layer of the conductive material has a larger electrical resistivity than the first layer of the conductive material. In an embodiment, the first layer of the conductive material and the third layer of the conductive material are deposited using a first deposition process, and wherein the second layer of the conductive material and the fourth layer of the conductive material are deposited using a second deposition process. In an embodiment, the first deposition process is a physical vapor deposition (PVD) process, and the second deposition process is an atomic layer deposition (ALD) process. In an embodiment, the method includes forming a second insulator layer on the fourth layer of the conductive material; and forming a third electrode, including depositing a sixth layer of the conductive material on the second insulator layer; and depositing a seventh layer of the conductive material on the fifth layer of the conductive material. In an embodiment, the second layer of the conductive material has a thickness in the range of 30 Å to 50 Å.

In an embodiment, a method includes performing a first deposition process to deposit a first electrode layer over a substrate, wherein the first electrode layer is a first conductive material; performing a second deposition process to deposit a second electrode layer on the first electrode layer, wherein the second electrode layer is the first conductive material, wherein the second deposition process is different from the first deposition process; depositing an insulating material on the second electrode layer; performing the first deposition process to deposit a third electrode layer on the insulating material, wherein the third electrode layer is a first conductive material; performing the second deposition process to deposit a fourth electrode layer on the third electrode layer, wherein the fourth electrode layer is the first conductive material; and performing a high pressure anneal (HPA) process on the substrate. In an embodiment, the method includes depositing a fifth electrode layer between the first electrode layer and the second electrode layer, wherein the fifth electrode layer is a second conductive material. In an embodiment, the second conductive material is tungsten. In an embodiment, the first conductive material is tantalum nitride. In an embodiment, the first deposition process is a physical vapor deposition (PVD) process. In an embodiment, the second deposition process is an atomic layer deposition (ALD) process. In an embodiment, the second electrode layer has a greater proportion of (200) crystalline orientation than the first electrode layer.

In an embodiment, a structure includes a dielectric layer sandwiched between a first electrode and a second electrode, wherein the first electrode and the second electrode each include a first layer of a conductive material and a second layer of the conductive material on the first layer of the conductive material, wherein the first layer has a greater density than the second layer; a first contact plug electrically contacting the first electrode; and a second contact plug electrically contacting the second electrode. In an embodiment, the second layer is thinner than the first layer. In an embodiment, the structure includes an interfacial layer between the dielectric layer and the second layer of the first electrode, wherein the interfacial layer includes oxygen. In an embodiment, the conductive material is titanium nitride. In an embodiment, the second layer has a density in the range of 4 g/cm³ to 5 g/cm³.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
forming a first electrode, comprising:
depositing a first layer of a conductive material; and
depositing a second layer of the conductive material on the first layer of the conductive material;
forming a first insulator layer on the second layer of the conductive material; and
forming a second electrode, comprising:
depositing a third layer of the conductive material over the first insulator layer; and
depositing a fourth layer of the conductive material over the third layer of the conductive material.

2. The method of claim 1, wherein forming the second electrode further comprises depositing a fifth layer of the conductive material over the first insulator layer.

3. The method of claim 1 further comprising annealing the first insulator layer in a hydrogen atmosphere.

4. The method of claim 1, wherein the second layer of the conductive material has a larger electrical resistivity than the first layer of the conductive material.

5. The method of claim 1, wherein the first layer of the conductive material and the third layer of the conductive material are deposited using a first deposition process, and wherein the second layer of the conductive material and the fourth layer of the conductive material are deposited using a second deposition process.

6. The method of claim 5, wherein the first deposition process is a physical vapor deposition (PVD) process, and the second deposition process is an atomic layer deposition (ALD) process.

7. The method of claim 1 further comprising:
forming a second insulator layer on the fourth layer of the conductive material; and
forming a third electrode, comprising:
depositing a fifth layer of the conductive material on the second insulator layer; and
depositing a sixth layer of the conductive material on the fifth layer of the conductive material.

8. The method of claim 1, wherein the second layer of the conductive material has a thickness in the range of 30 Å to 50 Å.

9. A method comprising:
performing a first deposition process to deposit a first electrode layer over a substrate, wherein the first electrode layer is a first conductive material;
performing a second deposition process to deposit a second electrode layer on the first electrode layer, wherein the second electrode layer is the first conductive material, wherein the second deposition process is different from the first deposition process;
depositing an insulating material on the second electrode layer;
performing the first deposition process to deposit a third electrode layer on the insulating material, wherein the third electrode layer is the first conductive material;
performing the second deposition process to deposit a fourth electrode layer on the third electrode layer, wherein the fourth electrode layer is the first conductive material; and
performing a high pressure anneal (HPA) process on the substrate.

10. The method of claim 9 further comprising depositing a fifth electrode layer between the first electrode layer and the second electrode layer, wherein the fifth electrode layer is a second conductive material.

11. The method of claim 10, wherein the second conductive material is tungsten.

12. The method of claim 9, wherein the first conductive material is tantalum nitride.

13. The method of claim 9, wherein the first deposition process is a physical vapor deposition (PVD) process.

14. The method of claim 9, wherein the second deposition process is an atomic layer deposition (ALD) process.

15. The method of claim 9, wherein the second electrode layer has a greater proportion of (200) crystalline orientation than the first electrode layer.

16. A structure comprising:
a dielectric layer sandwiched between a first electrode and a second electrode, wherein the first electrode and the second electrode each comprise:
a first layer of a conductive material; and
a second layer of the conductive material on the first layer of the conductive material, wherein the first layer has a greater density than the second layer;
a first contact plug electrically contacting the first electrode; and
a second contact plug electrically contacting the second electrode.

17. The structure of claim 16, wherein the second layer is thinner than the first layer.

18. The structure of claim 16 further comprising an interfacial layer between the dielectric layer and the second layer of the first electrode, wherein the interfacial layer comprises oxygen.

19. The structure of claim 16, wherein the conductive material is titanium nitride.

20. The structure of claim 16, wherein the second layer has a density in the range of 4 g/cm³ to 5g/cm³.
